(19) United States
(12) Patent Application Publication
(10) Pub. No.: US 2025/0221210 A1
(43) Pub. Date: Jul. 3, 2025

(54) Display Panel and Display Device Including the Same

(71) Applicant: LG Display Co., Ltd, Seoul (KR)

(72) Inventors: Young Min Jeong, Paju-si (KR); Won Ho Lee, Paju-si (KR); Seung Hwan Shin, Paju-si (KR)

(21) Appl. No.: 18/966,035

(22) Filed: Dec. 2, 2024

(30) Foreign Application Priority Data
Dec. 29, 2023 (KR) 10-2023-0197828

(51) Int. Cl. H10K 59/131; H10K 59/80; H10K 59/95

(52) U.S. Cl. CPC H10K 59/131; H10K 59/80521; H10K 59/95

(57) ABSTRACT

A display panel includes a display region where a plurality of pixels are disposed, a non-display region outside the display region, a pad portion including a plurality of pad electrodes disposed in the non-display region, a link portion disposed between the display region and the pad portion, a cathode common electrode overlapping a portion of the display region and the link portion to supply a cathode voltage to cathode electrodes of the pixels, and a line portion disposed on the pad portion and the link portion to be in contact with the cathode common electrode.

### CROSS-REFERENCE TO RELATED APPLICATION

This application claims priority to and the benefit of Republic of Korea Patent Application No. 10-2023-0197828, filed on Dec. 29, 2023, which is incorporated by reference in its entirety.

### BACKGROUND

### 1. Field of Technology

The present disclosure relates to a display panel and a display device including the same.

### 2. Discussion of Related Art

An electroluminescence display device displays images using self-luminous elements, and thus does not require a separate light source, for example, a backlight unit, and can be implemented in thin and various forms.

The electroluminescence display device includes an organic light-emitting display device in which an organic light-emitting diode (OLED) is disposed and an inorganic light-emitting display device (hereinafter, referred to as “an LED display device”) in which an inorganic light-emitting diode (hereinafter, referred to as “an LED”) is disposed.

Each pixel of the electroluminescence display device includes a light-emitting element which emits light according to current. Cathode electrodes of the light-emitting elements respectively disposed in pixels may be connected to a cathode common electrode in common to receive a cathode voltage through the cathode common electrode. The cathode common electrode may be connected to a pad disposed in a non-display region of a display panel. In this case, the current density nay be high at a bottleneck portion where current is concentrated between the cathode common electrode and the pad. The higher the current density in the bottleneck portion, the larger the amount of heat generated in the bottleneck portion, which may melt or ignite a polarization plate disposed on the display panel. Further, due to the bottleneck portion of the cathode common electrode, it is difficult to implement a narrow bezel which reduces the non-display region of the display panel.

### SUMMARY

The present specification is directed to solve the above-described needs and/or problems.

The present specification provides a display panel capable of reducing the current density and heat generation of an electrode to which a cathode voltage is applied, and a display device including the same.

The technical problems to be solved by the present specification are not limited to the above-mentioned technical problems, and other technical problems which are not mentioned will be clearly understood by those skilled in the art from the following description.

The technical problems may be solved by a display panel including a display region where a plurality of pixels are disposed, a non-display region outside the display region, a pad portion including a plurality of pad electrodes disposed in the non-display region, a link portion disposed between the display region and the pad portion, a cathode common electrode overlapping a portion of the display region and the link portion to supply a cathode voltage to cathode electrodes of the pixels, and a line portion disposed on the pad portion and the link portion to be in contact with the cathode common electrode.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a plan view illustrating a display device according to one embodiment of the present disclosure;

FIG. 2 is a view illustrating dummy channels of a chip on film (COF) according to one embodiment of the present disclosure;

FIG. 3 is an enlarged view of portion ‘E’ shown in FIG. 1 according to one embodiment of the present disclosure;

FIGS. 4A and 4B are cross-sectional views illustrating a cross-sectional structure of a display panel taken along cut line A˜A′ in FIG. 3 according to one embodiment of the present disclosure;

FIG. 5 is a cross-sectional view illustrating a cross-sectional structure of the display panel taken along cut line B˜B′ in FIG. 3 according to one embodiment of the present disclosure;

FIGS. 6A and 6B are cross-sectional views illustrating a cross-sectional structure of the display panel taken along cut line C˜C′ in FIG. 3 according to one embodiment of the present disclosure; and

FIGS. 7A and 7B are cross-sectional views illustrating cross-sectional structures of lines in a non-display region and an electrode in a display region according to various embodiments of the present disclosure.

### DETAILED DESCRIPTION

Advantages and features of the present disclosure, and methods of achieving them will become apparent with reference to the following embodiments, which are described in detail, in conjunction with the accompanying drawings. The present disclosure is not limited to the embodiments to be described below and may be implemented in various forms different from each other, the embodiments are only provided to completely disclose the present disclosure and completely convey the scope of the present disclosure to those skilled in the art, and the present disclosure is defined by the disclosed claims.

Since the shapes, sizes, proportions, angles, numbers, and the like disclosed in the drawings for describing the embodiments of the present disclosure are only exemplary, the present disclosure is not limited to the items shown in the drawings. Throughout the specification, the same reference numerals refer to substantially the same components. Further, in describing the present disclosure, when it is determined that a detailed description of related known technology may unnecessarily obscure the gist of the present disclosure, the detailed description thereof will be omitted.

When ‘providing,’ ‘including,’ ‘having,’ ‘comprising,’ and the like mentioned in the present specification are used, other parts may be added unless ‘only’ is used. A component is expressed in a singular form may also be interpreted as a plural form unless explicitly stated otherwise.

In interpreting the components, it should be understood that an error range is included even when there is no separate explicit description.

When a position relationship and an interconnection relationship between two components such as ‘on,’ ‘at an upper portion,’ ‘at a lower portion,’ ‘next to,’ ‘connect or couple,’ ‘crossing or intersecting,’ or the like are described, one or more other components may be interposed between the components unless there is a mention such as ‘immediately’ or ‘directly.’

When a temporal relationship is described as ‘after,’ in succession to,′ ‘and then,’ ‘before,’ or the like, the temporal relationship may not be continuous on a time axis unless ‘immediately’ or ‘directly’ is used.

First, second, and the like may be used in front of names of components to distinguish the components, but functions or structures are not limited by these ordinal numbers or component names. For convenience of description, the ordinal numbers in front of the name of the same components may be different between embodiments.

The following embodiments may be partially or fully combined with each other, and technically, various types of interconnections and driving are possible. The embodiments may be implemented independently of each other or may be implemented together in a related relationship.

Hereinafter, various embodiments of the present disclosure will be described in detail with reference to the accompanying drawings.

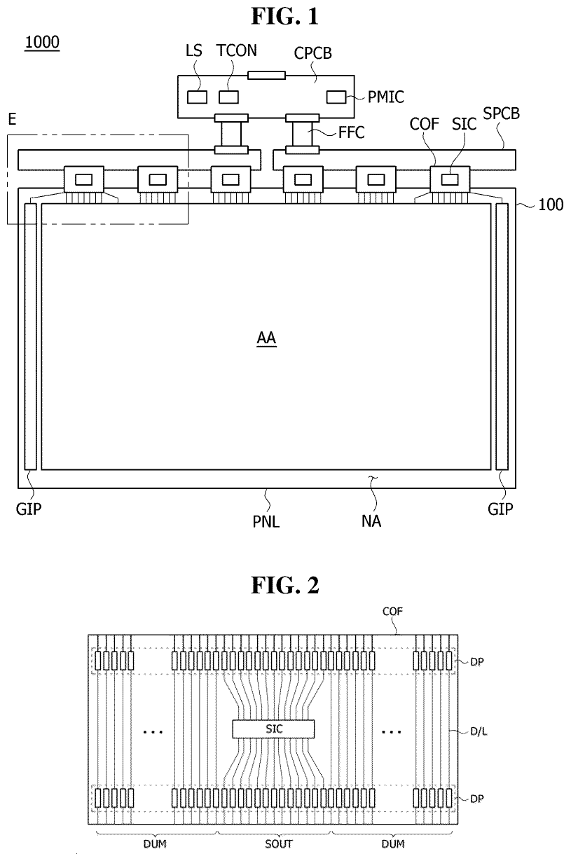

FIG. 1 is a plan view illustrating a display device according to an embodiment of the present disclosure.

Referring to FIG. 1, a display device 1000 according to one embodiment of the present disclosure includes a display panel PNL including a display region AA and a non-display region NA disposed outside the display region AA, and a display panel driver for writing pixel data of an input image in each of pixels of the display panel PNL.

The display region AA of the display panel PNL includes a plurality of data lines, a plurality of gate lines crossing the data lines, and a plurality of pixels connected to the corresponding data lines and gate lines. The pixels may include one or more transistors, capacitors, and light-emitting elements. The light-emitting element may be implemented as an organic light-emitting diode (hereinafter, referred to as “OLED”) including an anode electrode and a cathode electrode, or an inorganic light-emitting element such as a micro-LED. The light-emitting element may be driven by current from a driving element implemented as a transistor to emit light.

The display panel driver includes a data driving circuit which converts the pixel data of the input image to a data voltage and supplies the data voltage to the data lines of the display panel PNL, a gate driving circuit GIP which supplies pulses of a gate signal synchronized with the data voltage to the gate lines, and a timing controller TCON for controlling an operation timing of the data driving circuit and the gate driving circuit GIP.

In FIG. 1, the data driving circuit is integrated with a source drive integrated circuit (IC) SIC and connected to the data lines. The gate driving circuit GIP is disposed in the non-display region NA of the display panel PNL along with the display region AA and connected to gate lines GL through a gate in panel (GIP) process.

The gate driving circuit GIP may supply gate signal pulses to gate lines while shifting the gate signal pulses using one or more shift registers or edge triggers. The gate signal may include a scan signal and a light-emitting signal. In this case, the gate driving circuit GIP may include a shift register which sequentially outputs the pulses of the scan signal and a shift register (or an edge trigger) which sequentially outputs the pulses of the light-emitting signal. The gate driving circuit GIP may receive a start signal and a clock signal through a level shifter to output the pulses of the gate signal, and may supply the pulses to the gate lines while shifting the pulses.

The timing controller TCON receives input image data from an external host system and transmits the image data to the source drive IC SIC. The timing controller TCON receives a timing signal such as a vertical/horizontal synchronization signal, a data enable signal, a clock signal, or the like to generate timing control signals for controlling the operation timing of the source drive IC SIC and the gate driving circuit GIP.

The source drive IC SIC may be mounted on a bendable flexible circuit substrate 100, for example, a chip on film (COF). In the case of a large screen display device, a source printed circuit board (PCB) SPCB may be separated into two source printed circuit boards. The COFs are split and connected to two source PCBs SPCB. The COFs are adhered to the substrate 100 and the source PCBs SPCB through an anisotropic conductive film (ACF). The input terminals of the COFs are electrically connected to the output terminals of the source PCBs SPCB. The input terminals of source COFs COF are electrically connected to data pads formed on the substrate 100 through the ACF.

The timing controller TCON receives the pixel data of the input image and the timing signals synchronized with this data from a host system omitted in the drawings. The timing signals may include a vertical synchronization signal Vsync, a horizontal synchronization signal Hsync, and a data enable signal DE. Since a vertical period and a horizontal period may be known by a method of counting the data enable signal DE, the vertical synchronization signal Vsync and the horizontal synchronization signal Hsync may be omitted. The data enable signal DE has a period of one horizontal period 1H.

The timing controller TCON generates a signal or timing information for controlling the operation timing of the source drive IC SIC and the gate driving circuit GIP based on the timing signals Vsync, Hsync, and DE received from the host system. Accordingly, the source drive IC SIC and the gate driving circuit GIP may be controlled.

A gate timing control signal generated from the timing controller TCON may be input to the gate driving circuit GIP through the level shifter. The level shifter receives the gate timing control signal and generates the start signal and a clock to transmit the start signal and the clock to the gate driving circuit GIP. An input signal of the level shifter is a signal of a digital signal voltage level. An output signal of the level shifter includes a clock of an analog voltage which swings between a gate-high voltage and a gate-low voltage. A data timing control signal generated from the timing controller TCON is transmitted to the source drive IC SIC. The gate-high voltage and the gate-low voltage are voltages which turn on/off a transistor used as a switch element which drives the pixels and the gate driving circuit GIP.

A power circuit PMIC outputs a constant voltage required to drive the pixels of the display panel PNL and circuits of the display panel driver, for example, an IC driving voltage Vcc, the gate-high voltage, the gate-low voltage, a pixel driving voltage, a cathode voltage, a gamma reference voltage, or the like.

The timing controller TCON, the level shifter, and the power circuit PMIC may be disposed on a control board CPCB. The control board CPCB may be connected to the source PCB SPCB through a flexible flat cable FFC. The gate-high voltage, the gate-low voltage, and the like may be supplied to the gate driving circuit GIP with the gate timing control signals required to drive the gate driving circuit GIP, that is, a start pulse and a shift clock through dummy channels DUM disposed on a COF film and line on glass (LOG) lines disposed on the substrate of the display panel PNL.

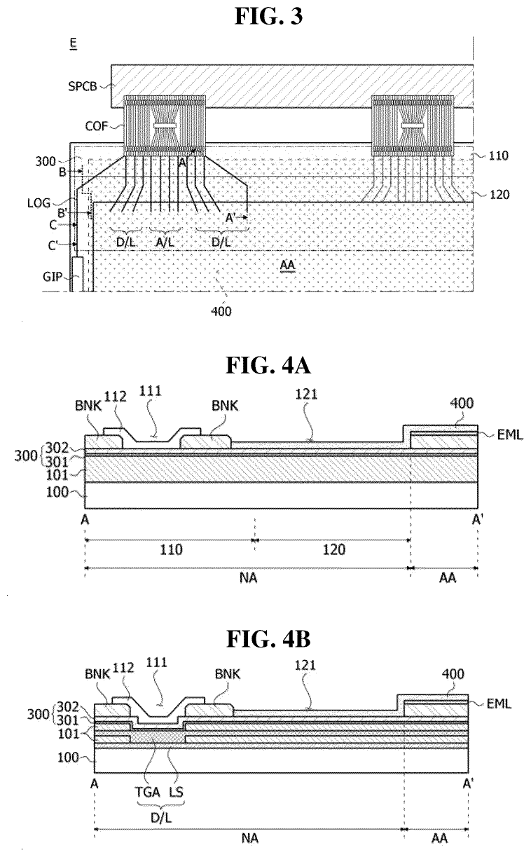

FIG. 2 is a view illustrating the dummy channels of the COF, and FIG. 3 is an enlarged view of portion ‘E’ shown in FIG. 1 according to one embodiment.

Referring to FIGS. 2 and 3, the COF includes source channels SOUT connected to the source drive IC SIC and dummy channels DUM irrelevant to the source drive IC SIC. A first dummy channel group and a second dummy channel group are separated with the source drive IC SIC therebetween. Each of the first and second dummy channel groups may include 10 to 20 dummy channels.

Each of the source channels SOUT and the dummy channels DUM includes a first pad, a second pad, and a dummy line D/L which connects the pads. The first pad is connected to an output pad of the source PCB SPCB through an ACF, and the second pad is connected to pads of the substrate 100 through an ACF. The second pads may be data pad electrodes DPD and power voltage pad electrodes VSPD.

Among the dummy channels DUM, the dummy lines D/L formed on the film of the COF close to the gate driving circuit GIP may be connected to a LOG line LOG. The COF close to the gate driving circuit GIP may be a COF disposed at one end or both ends of the substrate 100. Among the dummy channels DUM, the dummy lines D/L not connected to the LOG line LOG may be connected to a cathode common electrode 400 through a low-resistance line portion 300 with a large area in a contact portion 121.

The dummy lines D/L may be connected to the cathode common electrode 400 to supply a voltage required to drive a pixel array in the display region.

As shown in FIG. 3, a pad portion 110 may be disposed in the non-display region NA on the display panel PNL, and a link portion 120 may be disposed between the pad portion 110 and the display region AA. The link portion 120 may include the LOG line LOG connected to source lines connected to the source drive IC SIC and the gate driving circuit GIP, and the dummy lines D/L connected to the cathode common electrode 400 to apply the cathode voltage output from the power circuit PMIC to the cathode common electrode 400.

The cathode common electrode 400 may be formed as a single surface electrode disposed on one side of the display region AA, the link portion 120, and the pad portion 110 when viewed from a plane of the display panel PNL.

The low-resistance line portion 300 may be disposed relatively widely on the non-display region NA including the pad portion 110 and the link portion 120 and may be disposed to extend up to a portion of an upper side of the display region AA to partially overlap the display region AA.

In a partial region on the pad portion 110 and the link portion 120, the cathode common electrode 400 and the low-resistance line portion 300 may be electrically connected by disposing the contact portion 121.

FIGS. 4A and 4B are cross-sectional views illustrating a cross-sectional structure of the display panel taken along cut line A˜A′ in FIG. 3 according to one embodiment. At cut line A˜A′, the cross-sectional structure of the display panel PNL may be a cross-sectional structure shown in FIG. 4A or a cross-sectional structure shown in FIG. 4B.

Referring to FIG. 4A, the display panel PNL may include the pad portion 110 and the link portion 120 in the non-display region NA adjacent to an upper side of the display region AA. The pad portion 110 includes a plurality of pads 112.

Each of the pads 112 includes a COF connection portion 111 exposed between bank layers BNK. An output terminal of the COF is electrically connected to the COF connection portion 111 through the corresponding ACF. The link portion 120 includes a plurality of data link portions connected to the plurality of data lines. The cathode common electrode 400 is partially disposed in the link portion 120 and extends to the display region AA to be connected to the cathode electrode of each of the light-emitting elements disposed in the display region AA in common.

The link portion 120 may include one or more contact portions 121. The wide low-resistance line portion 300 and the cathode common electrode 400 may be directly connected to each contact portion 121.

A planarization layer 101 is disposed on the substrate 100 of the display panel PNL. The low-resistance line portion 300 disposed as a multi-metal layer may be formed on the planarization layer 101. The low-resistance line portion 300 may be disposed on the planarization layer 101 as a double metal layer in which Cu 302 is disposed on indium tin oxide (ITO) 301. The low-resistance line portion 300 may be relatively widely disposed on the non-display region NA including the pad portion 110 and the link portion 120 and may extend up to a portion of an upper side of the display region AA to partially overlap the display region AA. The low-resistance line portion 300 may be directly electrically connected to the plurality of pads 112 at the COF connection portion 111 of the pad portion 110 and electrically connected to the cathode common electrode 400 at the contact portion 121. The contact portion 121 may be formed in an entire area of the pad portion 110 and the link portion 120 of the non-display region NA except for a region where the data lines are disposed and a region where the COF connection portion 111 of the pad portion 110 and the bank layers BNK disposed around the COF connection portion 111 are formed.

In the case of the non-display region NA, the bank layers BNK may be disposed on the low-resistance line portion 300 except for the contact portion 121. In the display region AA, an organic light-emitting layer EML and the cathode common electrode 400 may be stacked on the bank layer BNK. When a current flows through the light-emitting element in each of the pixels of the display region AA, light in a visible light wavelength band may be emitted from the organic light-emitting layer EML.

Both the COF connection portion 111 and the contact portion 121 may be formed in the non-display region NA, and the cathode common electrode 400 may be formed integrally with the upper portion of the display region AA and the contact portion 121.

Referring to FIG. 4B, first and second metal layers LS and TGA may be disposed under the low-resistance line portion 300. As a three-stage parallel line structure in which the first metal layer LS and the second metal layer TGA are stacked is formed, the resistance value of lines may be reduced.

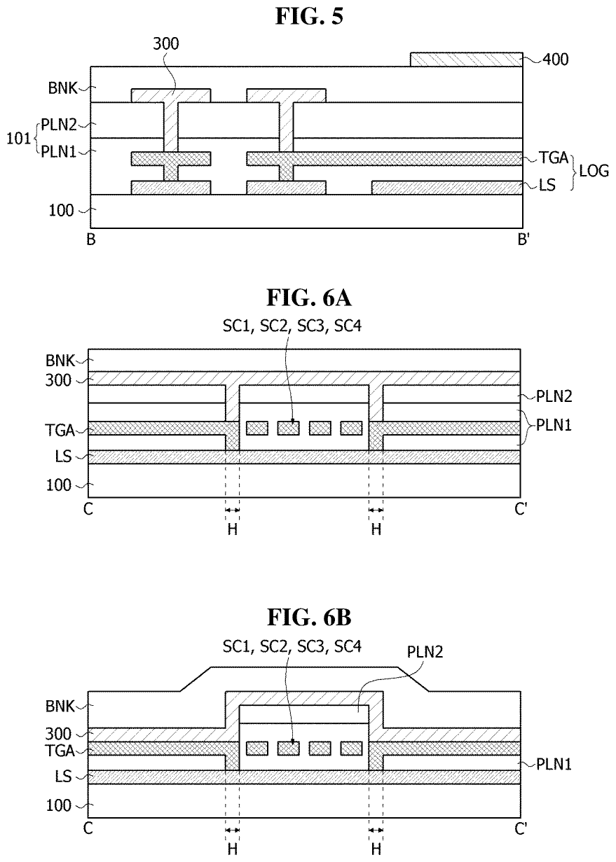

FIG. 5 is a cross-sectional view illustrating a cross-sectional structure of the display panel taken along cut line B˜B′ in FIG. 3 according to one embodiment.

Referring to FIG. 5, in order to transmit a clock signal SCCLK to the gate driving circuit GIP on the substrate 100, GIP CLK lines may be disposed in the first metal layer LS and the second metal layer TGA. The planarization layer 101 may be formed to protect and planarize the first metal layer LS and the second metal layer TGA. The planarization layer 101 may be composed of an organic insulating material. The planarization layer 101 may be formed as a single layer, but preferably, may be disposed as a plurality of planarization layers PLN1 and PLN2 as shown in FIG. 5. The first metal layer LS and the second metal layer TGA may be the LOG lines LOG connected to the dummy lines D/L of the COF disposed at one side end or both side ends of the substrate 100. In order to reduce the resistance of the first metal layer LS and the second metal layer TGA, the low-resistance line portion 300 may be additionally formed on the second metal layer TGA. The bank layer BNK may be disposed on the low-resistance line portion 300 and the planarization layer 101. The cathode common electrode 400 formed to extend from the display region may be disposed on the bank layer BNK to receive the cathode voltage from the contact portion 121.

FIGS. 6A and 6B are cross-sectional views illustrating a cross-sectional structure of the display panel taken along cut line C˜C′ in FIG. 3 according to one embodiment. At cut line C˜C′, the cross-sectional structure of the display panel PNL may be a cross-sectional structure shown in FIG. 6A or a cross-sectional structure shown in FIG. 6B.

Referring to FIGS. 6A and 6B, lines for transmitting the SCCLK signal to the gate driving circuit GIP may be disposed as a line portion of three stacked layers. Since it is the same as the GIP CLK line shown in FIG. 5 except for a shape of the second metal layer TGA and a contact state between lines, overlapping descriptions will be omitted. The second metal layer TGA disposed on the first metal layer LS may be disposed in an island contact structure with a disconnected middle portion for circuit unit signal supply. Lines SC1, SC2, SC3, and SC4 for supplying signals may be disposed in a space where the second metal layer TGA is disconnected. When the low-resistance line portion 300 is in contact with the second metal layer TGA, contact holes H may be overlappingly disposed at the same position as contact holes H disconnected in the middle portion of the lines to reduce the resistance of the GIP CLK lines as shown in FIG. 6A, or the low-resistance line portion 300 may be disposed to be entirely in contact with an upper portion of the second metal layer TGA and then connected to upper contact holes H of the disconnected second metal layer TGA as shown in FIG. 6B.

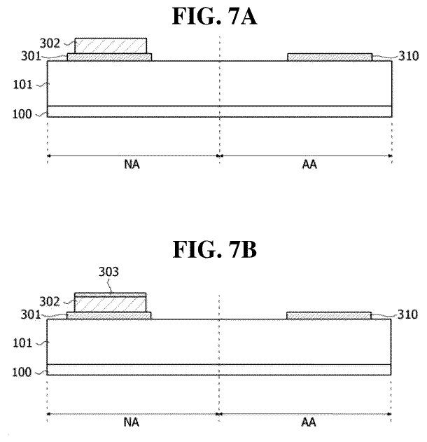

FIGS. 7A and 7B are cross-sectional views of the line portions in the non-display region NA and an electrode portion in the display region according to various embodiments of the present disclosure.

Referring to FIGS. 7A and 7B, the low-resistance line portion 300 of the non-display region NA and an electrode portion 310 of the display region AA of the present disclosure may be simultaneously formed by applying a half-tone mask process to an upper portion of the planarization layer 101. The electrode portion 310 of the display region AA may be formed of a single layer of a transparent electrode such as ITO using a half-tone mask, and the low-resistance line portion 300 of the non-display region NA may be disposed by additionally stacking the Cu 302 or the like on the ITO 301 such as the electrode portion 310. The low-resistance line portion 300 of the non-display region NA is not limited thereto and may be a multi-metal layer of MoTi/Cu/ITO in which MoTi 303 is additionally disposed on a Cu layer as shown in FIG. 7B. A stacked structure of the low-resistance line portion 300 is not limited thereto, and may include ITO/Al or ITO/Al/MoTi.

The display device according to the embodiments may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical apparatus, a desktop personal computer (PC), a laptop PC, a netbook computer, a workstation, a navigation device, a vehicle display device, a theater display device, a television, a wallpaper apparatus, a signage apparatus, a gaming apparatus, a notebook, a monitor, a camera, a camcorder, a home appliance, and the like. Further, the display device according to one or more embodiments of the present specification may be applied to an organic light-emitting lighting device or inorganic light-emitting lighting device.

According to the present specification, during an electrode process, a current bottleneck phenomenon can be prevented by adding a half-tone process to simultaneously form a line portion and an electrode portion and forming a line portion with a large area to which a cathode common electrode in a non-display region and a cathode voltage electrode are electrically connected.

In the case of a gate in panel (GIP) line portion, a narrow bezel can be implemented by reducing the margin of the line portion by additionally forming a dummy line on an existing line to decrease the resistance value of a GIP line.

The various and helpful advantages and effects of the present specification are not limited to the above-described contents, and other effects which are not mentioned will be clearly understood by those skilled in the art from the description above.

Since the contents of the specification described in the problem to be solved, the means to solve of the problem, and the effects described above do not specify the essential features of the claims, the scope of the claims is not limited by the items described in the contents of the specification.

Although the embodiments of the present disclosure have been described in more detail with reference to the accompanying drawings, the present disclosure is not necessarily limited to these embodiments, and may be variously modified without departing from the technical spirit of the present disclosure. Accordingly, the embodiments disclosed in the present disclosure are not intended to limit the technical spirit of the present disclosure, but to describe the technical spirit of the present disclosure, and the scope of the technical spirit of the present disclosure is not limited by these embodiments. Accordingly, the above-described embodiments should be understood in all respects as illustrative and not restrictive.

What is claimed is:

1. A display panel comprising:
a display region including a plurality of pixels;
a non-display region outside the display region;
a pad portion including a plurality of pad electrodes, the plurality of pad electrodes in the non-display region;
a link portion between the display region and the pad portion;
a cathode common electrode overlapping a portion of the display region and the link portion, the cathode common electrode supplying a cathode voltage to cathode electrodes of the plurality of pixels; and
a line portion on the pad portion and the link portion, the line portion in contact with the cathode common electrode.

2. The display panel of claim 1, wherein the plurality of pad electrodes include at least one data pad electrode and at least one power voltage pad electrode.

3. The display panel of claim 1, wherein the cathode common electrode includes a single surface electrode at one side of the display region, the link portion, and the pad portion when viewed from a plane of the display panel.

4. The display panel of claim 1, wherein the line portion includes multi-metal lines of indium tin oxide (ITO)/Cu, ITO/Cu/MoTi, ITO/Al, and ITO/Al/MoTi.

5. The display panel of claim 1, wherein the line portion is on the non-display region including the pad portion and the link portion, extends up to a portion of an upper side of the display region, and partially overlap the display region.

6. The display panel of claim 1, wherein the pad portion includes a chip on film (COF) connection portion that is connected to the line portion.

7. The display panel of claim 6, further comprising:
a contact portion in an entire area of the pad portion and the link portion except for a region where data lines are disposed and a region where the COF connection portion and a bank layer are around the COF connection portion.

8. The display panel of claim 7, wherein the cathode common electrode is electrically connected to the line portion at the contact portion.

9. The display panel of claim 1, further comprising:
a chip on film connected to the display panel,
wherein the chip on film includes a film substrate, a source drive integrated circuit (IC) mounted on the film substrate and outputs a data voltage corresponding to pixel data of an input image, and a plurality of dummy lines on the film substrate and spaced apart from the source drive IC.

10. The display panel of claim 1, further comprising:
a plurality of gate lines connected to the plurality of pixels;
one or more clock lines to which clock signals are applied; and
a gate driving circuit in the non-display region, the gate driving circuit connected to the one or more clock lines and connected to the plurality of gate lines,
wherein the one or more clock lines include a first metal layer, a second metal layer on the first metal layer and electrically connected to the first metal layer, and a second line portion on the second metal layer and electrically separated from the line portion, and electrically connected to the second metal layer.

11. The display panel of claim 10, wherein the second metal layer is disposed separately and is electrically connected to the first metal layer in a first contact hole that is at an end of the second metal layer.

12. The display panel of claim 11, wherein the second line portion and the second metal layer are electrically connected in a second contact hole that overlaps the first contact hole.

13. The display panel of claim 11, wherein the second line portion is entirely on the second metal layer and is electrically connected to the second metal layer.

14. A display device comprising:
a display panel including a display region including a plurality of pixels and a non-display region that is outside the display region;
a display panel driver configured to write pixel data of an input image in the plurality of pixels,
wherein the display panel includes a plurality of data lines, a plurality of gate lines crossing the plurality of data lines, a pad portion including a plurality of pad electrodes in the non-display region, a link portion between the display region and the pad portion, a cathode common electrode overlapping a portion of the display region and the link portion and supplies a cathode voltage to cathode electrodes of the plurality of pixels, and a line portion on the pad portion and the link portion and in contact with the cathode common electrode.
